(19) United States
(12) Patent Application Publication
(10) Pub. No.: US 2018/0278154 A1
(43) Pub. Date: Sep. 27, 2018

(54) SWITCHING POWER SUPPLY APPARATUS, DRIVING METHOD FOR SWITCHING POWER SUPPLY, AND DRIVING PROGRAM FOR SWITCHING POWER SUPPLY

(71) Applicant: NEC Corporation, Minato-ku, Tokyo (JP)

(72) Inventor: Takashi YAMANE, Tokyo (JP)

(73) Assignee: NEC Corporation, Minato-ku, Tokyo (JP)

(21) Appl. No.: 15/756,703

(22) PCT Filed: Sep. 12, 2016
(86) PCT No.: PCT/JP2016/004139

§ 371 Date: Mar. 1, 2018

(30) Foreign Application Priority Data
Sep. 15, 2015 (JP) 2015-181327

(51) Int. Cl. H02M 1/44; H02M 3/04; H03H 17/02

(52) U.S. Cl. CPC H02M 1/44; H02M 2001/0012; H03H 17/0213; H02M 3/04

(57) ABSTRACT

The present invention is aimed at providing a switching power supply apparatus enabling to avoid enhancement of noise of a specific frequency component. The present invention is a switching power supply apparatus provided with: a switching power supply configured to perform switching of input from a primary power source and thereby output a secondary power source; and a noise frequency analysis device configured to analyze frequency components of noise included in output of the primary power source or of the secondary power source, and accordingly cause the switching power supply to perform switching at a different frequency from a frequency of a maximum noise amplitude among the frequency components.

### TECHNICAL FIELD

The present invention relates to a switching power supply apparatus, a driving method for switching power supply, and a driving program for switching power supply.

### BACKGROUND ART

Recently, in an increased number of cases, a plurality of switching power supplies (for example, DC-DC converters) are installed in a single product. In such cases, when identical switching power supplies (with the same switching frequency) are used, a noise component of a frequency specific to a primary power source is enhanced, which makes it difficult to remove the noise by an existing power source filter and accordingly causes various harmful effects.

Recent products are often provided with a CPU (Central Processing Unit), and progress in increasing their functionality has been made year by year. By utilizing the CPU, advanced control has become possible.

Patent Literature 1 (PTL 1) discloses an ultrasonic diagnostic device using a plurality of switching power supplies, where the plurality of switching power supplies are operated at mutually different switching frequencies. PTL 1 describes that rail noise caused by superposition of switching frequencies can be reduced in that way.

Patent Literature 2 (PTL 2) discloses a switching power supply apparatus described below. When a power supply system is configured with a plurality of switching power supply apparatuses, beat noises of frequencies corresponding to differences between switching frequencies of respective ones of the plurality of switching power supply apparatuses are generated in output. To resolve the problem, a synchronous operation control circuit is provided in each of the switching power supply apparatuses, and one of the switching power supply apparatuses is set to be a master power supply and the others to be slave power supplies whose switching frequencies are determined based on an oscillation clock signal of the master power supply. PTL 2 describes that, in that way, switching frequencies of the respective switching power supply apparatuses become coincident with each other even when there is variance among individual oscillation clock signals and, accordingly, generation of beat noise can be prevented.

Patent Literature 3 (PTL 3) discloses a noise reduction method for a switching power supply apparatus using a plurality of switching power supply units. A modulation signal output unit for outputting modulation signals to control the switching power supply units is controlled by signals each representing a state of a switching element within a corresponding one of the switching power supply units, and it is enabled to change a configuration of the modulation signal output unit. In one example of a configuration of the modulation signal output unit, a frequency adjustment unit for changing frequencies of the modulation signals is provided. The frequency adjustment unit adjusts its output frequencies to reduce noise caused by the switching power supply units. Specifically, it sets the frequencies at those which do not affect measurement or the like.

FIG. 6 of PTL 3 shows a relationship between a measurement frequency for measuring a measured signal using a semiconductor test apparatus or the like and noise generated by the switching power supply units. FIG. 6(A) shows a case where the measurement frequency is in coincidence with a frequency in a frequency spectrum of the noise. In that case, the measurement is largely affected by the noise. PTL 3 describes that, in such a case, the noise spectrum can be shifted away from the measurement frequency, as in FIG. 6(B), by shifting output frequencies of the frequency adjustment unit.

### CITATION LIST

### Patent Literature

### [PTL 1] Japanese Patent Laid-Open No. 2014-83155

### [PTL 2] Japanese Patent Laid-Open No. 2012-151937

### [PTL 3] Japanese Patent Laid-Open No. 2011-10466

### SUMMARY OF THE INVENTION

### Technical Problem

In use of a plurality of switching power supplies, when switching frequencies of respective ones of the plurality of switching power supplies are the same, it may occur that noise of a specific frequency component is maximized and, accordingly, noise cannot be entirely removed by an existing power source filter composed of a capacitor, an inductor and the like. Some degree of noise suppression has been enabled by shifting switching timings of respective switching power supplies installed within a device away from each other. However, because a frequency of noise superposed on a primary power source supplied from outside is unknown, it has been impossible to avoid that a frequency of a noise component superposed on the primary power source becomes coincident with a switching frequency of a switching power supply in a product.

PTL 1 and PTL 2 are each an invention in relation to a problem to occur among a plurality of switching power supplies and, therefore, cannot resolve the problem in that a frequency of a noise component superposed on a primary power source becomes coincident with a switching frequency of a switching power supply.

The measurement frequency described in PTL 3 is a frequency of a signal output from a test target of the semiconductor test apparatus, and PTL 3 therefore cannot resolve the problem in that a frequency of a noise component superposed on a primary power source becomes coincident with a switching frequency of a switching power supply, similarly to PTL 1 and PTL 2.

While the above description has been given of a case of using a plurality of switching power supplies, even when only a single switching power supply is used, it is still the case that a frequency of noise superposed on a primary power source supplied from outside is unknown. Accordingly, even when only a single switching power supply is used, it may occur that a frequency of a noise component superposed on a primary power source becomes coincident with a switching frequency of the switching power supply.

An objective of the present invention is to resolve the problem described above and accordingly provide a switching power supply apparatus, a driving method for switching power supply and a driving program for switching power supply which can avoid that noise of a specific frequency component is enhanced.

### Solution to Problem

One aspect of the present invention is a switching power supply apparatus including: a switching power supply configured to perform switching of input from a primary power source and thereby output a secondary power source; and a noise frequency analysis device configured to analyze frequency components of noise included in output of the primary power source or of the secondary power source and cause the switching power supply to perform switching at a different frequency from a frequency of a maximum noise amplitude among the frequency components.

Another aspect of the present invention is a driving method for a switching power supply configured to perform switching of input from a primary power source and thereby output a secondary power source, the driving method including: analyzing frequency components of noise included in output of the primary power source or of the secondary power source; and causing the switching power supply to perform switching at a different frequency from a frequency of a maximum noise amplitude among the frequency components.

Another aspect of the present invention is a driving program for a switching power supply configured to perform switching of input from a primary power source and thereby output a secondary power source, the driving program causing a computer to execute: a process of analyzing frequency components of noise included in output of the primary power source or of the secondary power source; and a process of causing the switching power supply to perform switching at a different frequency from a frequency of a maximum noise amplitude among the frequency components.

### ADVANTAGEOUS EFFECTS OF THE INVENTION

According to the present invention, it is possible to provide a switching power supply apparatus, a driving method for switching power supply and a driving program for switching power supply which can avoid that noise of a specific frequency component is enhanced.

### BRIEF DESCRIPTION OF THE DRAWINGS

FIG. 1 is a block diagram showing a switching power supply (apparatus) of a first example embodiment of the present invention.

FIG. 2 is a block diagram showing a switching power supply (apparatus) of a second example embodiment of the present invention.

FIG. 3 is a diagram showing conversion of original data from time series data into frequency series data performed in the second example embodiment of the present invention.

FIG. 4 is a diagram illustrating background art and accordingly showing frequency series data in a case of making a switching power supply operate without monitoring of frequency components of a primary power source.

FIG. 5 is a flow chart illustrating operation of the switching power supply (apparatus) of the second example embodiment of the present invention.

FIG. 6 is a diagram illustrating the second example embodiment of the present invention and accordingly showing that overlap of frequency components of noise in a primary power source with a frequency component of noise generated by switching power supplies is avoided.

FIG. 7 is a diagram illustrating a third example embodiment of the present invention and accordingly showing that overlap among frequency components of noise is avoided by shifting switching frequencies of a plurality of switching power supplies away from each other.

FIG. 8 is a diagram illustrating a fourth example embodiment of the present invention and accordingly is a block diagram showing a switching power supply apparatus configured to detect frequency components of noise at the side of a secondary power source.

### DESCRIPTION OF EMBODIMENTS

### First Example Embodiment

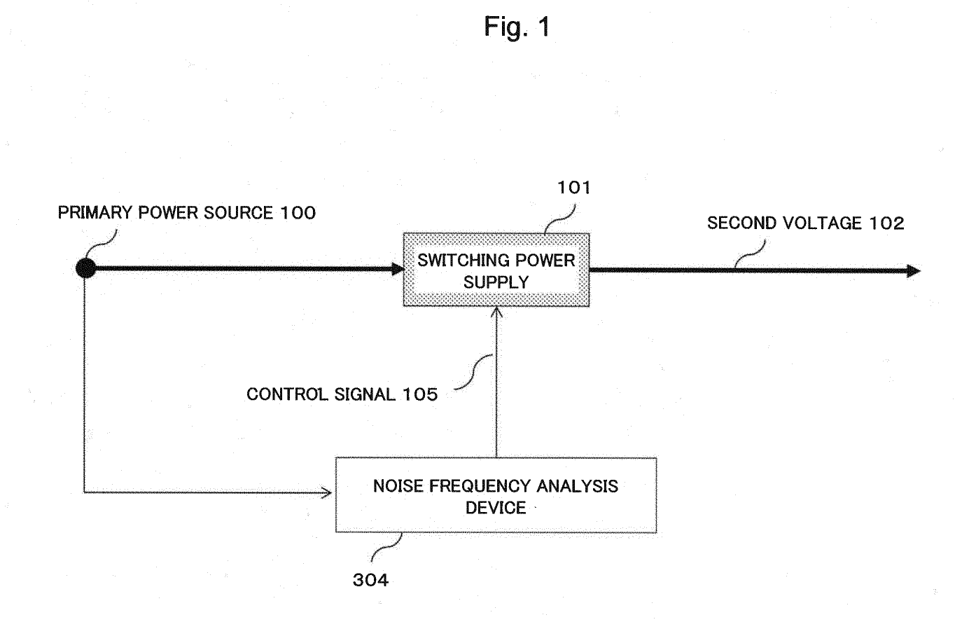

FIG. 1 is a block diagram showing a first example embodiment of the present invention. A switching power supply apparatus of the present example embodiment includes a switching power supply 101 and a noise frequency analysis device 304. The switching power supply 101 performs switching of input from a primary power source 100 and thereby outputs a secondary voltage 102. The secondary voltage 102 is equivalent to a secondary power source. The noise frequency analysis device 304 analyzes frequency components included in output of the primary power source 100, and accordingly outputs to the switching power supply 101 a control signal 105 for causing the switching power supply 101 to perform switching of the primary power source 100 at a different frequency from a frequency of noise at a maximum peak in the primary power source 100. In that way, it becomes possible, in the secondary power source, to avoid that a frequency of a noise component superposed on the primary power source becomes coincident with a switching frequency of the switching power supply 101 and accordingly prevent noise of a specific frequency component from being markedly enhanced.

### Second Example Embodiment

### <Configuration of the Example Embodiment>

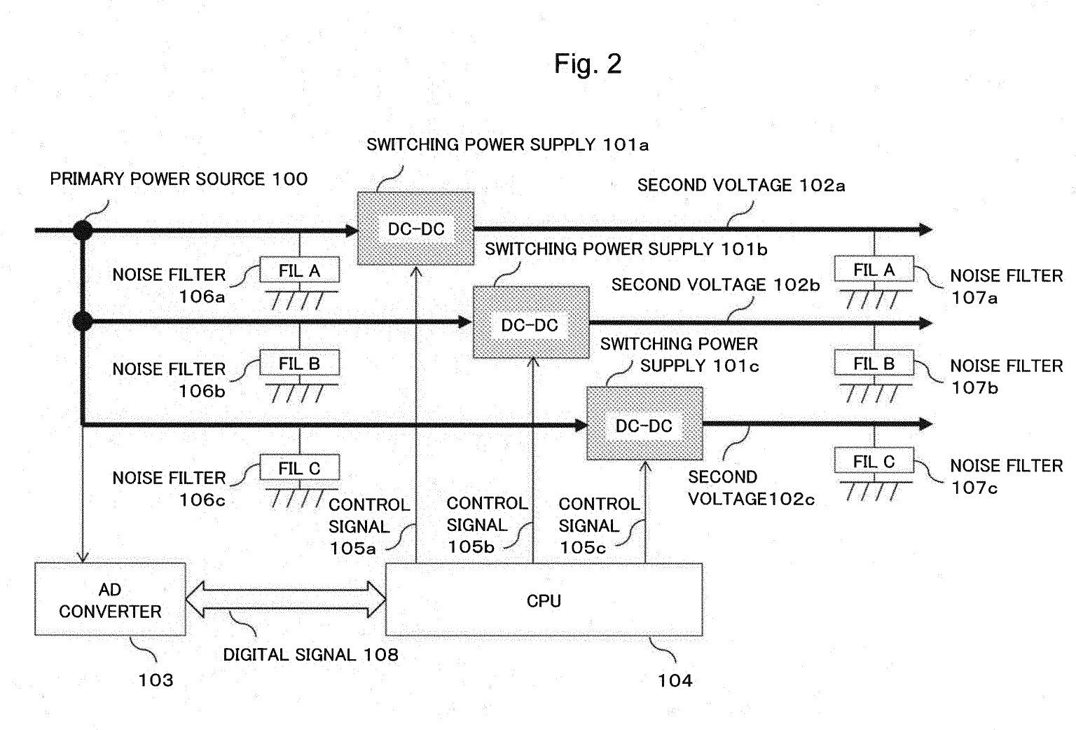

FIG. 2 is a block diagram showing a switching power supply apparatus of a second example embodiment of the present invention.

The switching power supply apparatus is provided with a plurality of switching power supplies (in FIG. 2, three switching power supplies 101a, 101b and 101c), for every one of which a same primary power source 100 is used. Control signals 105a, 105b and 105c are input from a CPU 104 to the respective switching power supplies 101a, 101b and 101c, which enables it to control their switching frequencies and switching timings. In the present example embodiment, a DC-DC converter is used for each of the switching power supplies 101a, 101b and 101c. For example, a DC-DC converter of a PWM (Pulse Width Modulation) method may be used.

An AD converter 103 performs AD (Analog-Digital) conversion of a voltage of the primary power source 100, and transmits a digital signal 108 into which the voltage value is digitized, to the CPU 104. The CPU 104 is configured with a microcomputer (Micro Processor or Micro Controller) and a DSP (Digital Signal Processor). The CPU 104 analyzes the digital data received from the AD converter 103 and outputs the control signals 105a, 105b and 105c to the respective switching power supplies 101a, 101b and 101c. The control signals 105a, 105b and 105c set switching frequencies and switching timings of the respective switching power supplies 101a, 101b and 101c.

Power source filters 106a, 106b and 106c are provided for the purpose of removing noise superposed on the supplied primary power source 100 and also of preventing switching noise generated by the switching power supplies 101a, 101b and 101c from being superposed on the primary power source 100. Power source filters 107a, 107b and 107c are provided for the purpose of removing the switching noise generated by the switching power supplies 101a, 101b and 101c.

### <Operation of the Example Embodiment>

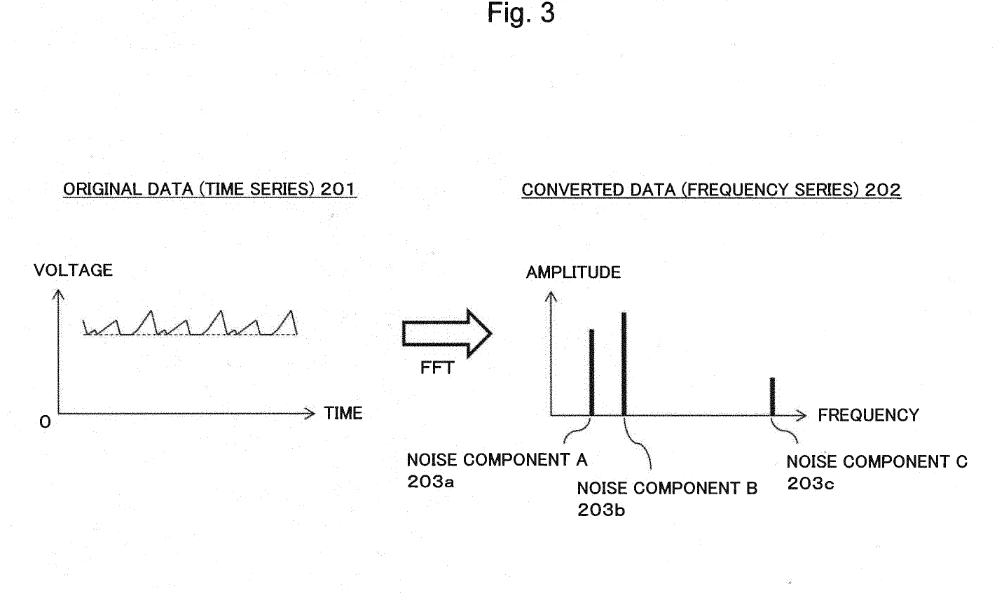

The AD converter 103 in FIG. 2 performs AD conversion of the primary power source 100 at a constant interval, thereby converting the voltage value into the digital signal 108. The CPU 104 receives the digital signal 108 as data representing time sequence variation of voltage of the primary power source 100 (original data 201 in FIG. 3).

The CPU 104 having received the digital signal 108 representing the voltage value of the primary power source 100 performs processing such as FFT (Fast Fourier Transform) on the digital signal 108, thereby converting the digital signal 108 into converted frequency series data 202 shown in FIG. 3. The vertical axis of FIG. 3 represents amplitude.

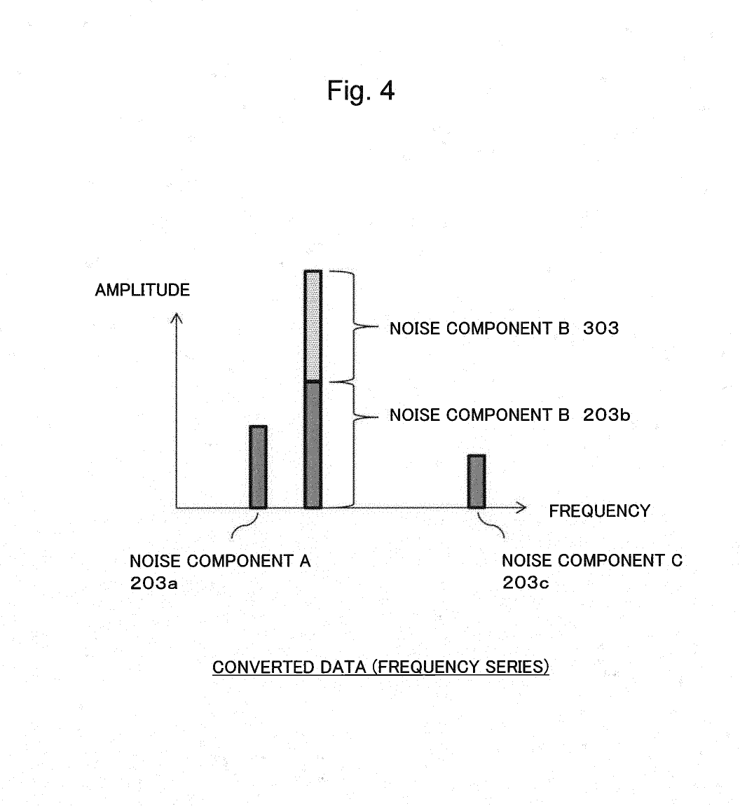

When the switching power supplies 101a, 101b and 101c are operated without monitoring of frequency components of an output voltage of the primary power source, the switching operation may be performed at the same frequency as that of a noise component B, 203b, which is inherently superposed on the primary power source, as shown in FIG. 4. In that case, noise 303 generated by the switching power supplies are further superposed in addition to the inherently present noise component B, 203b, which results in noise enhancement. In output of the switching power supplies, an AC component to be noise is included in addition to, and in superposition on, a DC component. The AC component is of the same frequency as the switching frequency of the switching power supplies, and is to be the noise 303.

In FIG. 4, the noise component 203b has a largest amplitude among the three noise components superposed on the primary power source and, when the noise component 203b and a noise component of the switching power supplies are of the same frequency, the noise component at that frequency becomes larger than other noise components 203a and 203c each having a smaller amplitude than the noise component 203b. In that case, noise removal by noise filters may become impossible. As a result of that a noise at a specific frequency is maximized, it may be impossible to remove noise components entirely by means of existing primary power source filters (106a, 106b and 106c in FIG. 2). It may also occur that large noise is superposed also on the switching supply outputs (secondary voltages 102a to 102c in FIG. 2) and cannot be removed by the power source filters 107a to 107c of FIG. 2. An LSI (Large Scale Integration) is often coupled to output of a power source filter, that is, output of a switching power supply apparatus, and there has been progress in voltage reduction for recent LSIs, whose fatal malfunction accordingly is caused even by only a small amount of noise.

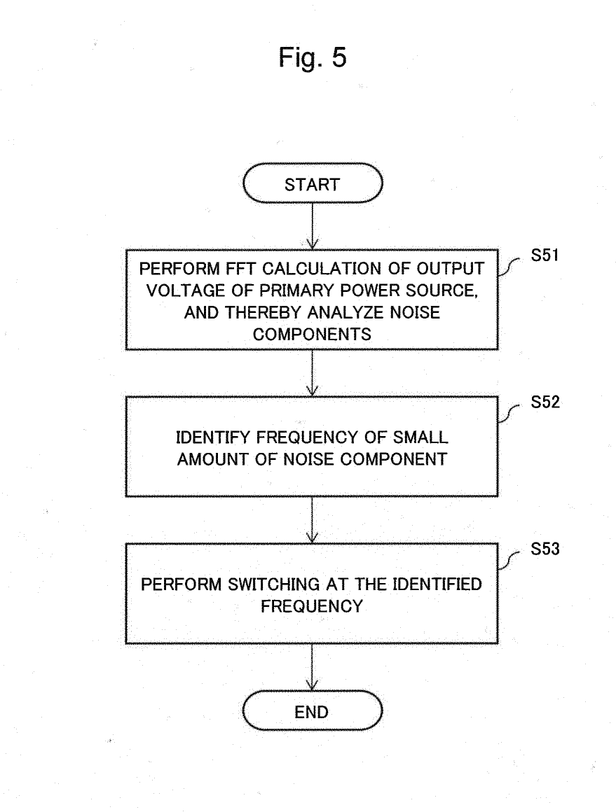

Considering the situation, in the present example embodiment, as shown in a flow chart of FIG. 5, before making the switching power supplies 101a, 101b and 101c start their operation, the CPU 104 performs

FFT calculation of the primary power source and thereby obtains the noise components 203a, 203b and 203c in the frequency domain (S51). From the data 202, a frequency of a small amount of noise component is identified (S52). The CPU 104 controls the switching power supplies 101a, 101b and 101c to perform switching at the frequency of a small amount of noise superposed on the primary power source, through the respective control signals 105a, 105b and 105c (S53). For example, when a frequency of a noise component having a largest amplitude among noise components in the primary power source is 500 KHz, and 400 KHz or 600 KHz, each being 100 KHz away from 500 KHz, is a frequency of a small amount of noise component, the switching is performed at a switching frequency of 400 KHz or 600 KHz. In the present case, the switching is performed at 600 KHz. The switching frequency also does not overlap with either of frequencies of the other noise components 203a and 203c, which are noise components not having a largest amplitude. In the present example embodiment, switching frequencies of respective ones of the three switching power supplies are assumed to be the same.

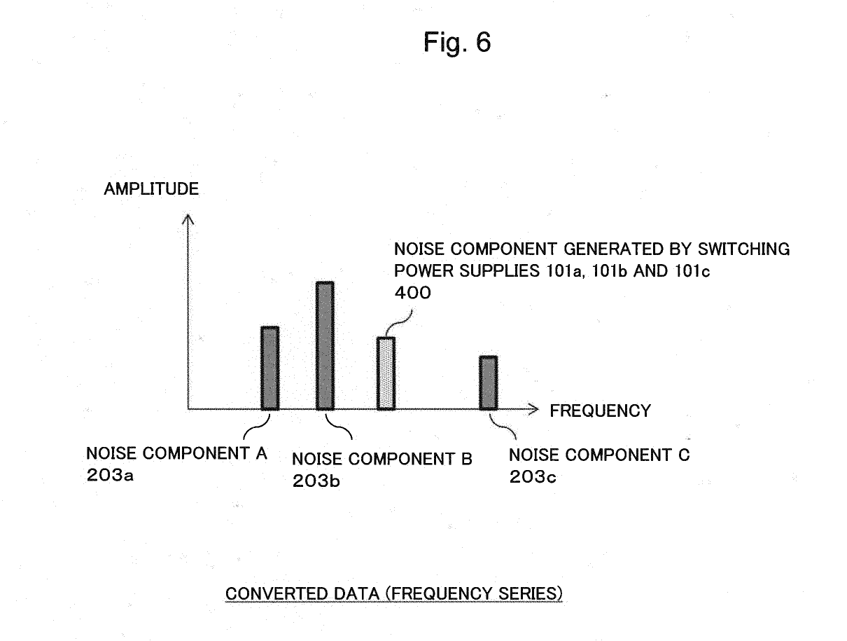

Thereby, as shown in FIG. 6, the noise components 203a, 203b and 203c superposed on the primary power source each become of a different frequency from the frequency of a noise component 400 generated by switching of the switching power supplies 101a, 101b and 101c, and there accordingly is no overlap between the noise components. As a result, it becomes easy to prevent noise of a specific frequency component from being markedly enhanced and to perform noise removal by means of existing small-size power source filters (106a, 106b and 106c in FIG. 2). Further, in terms also of noise generated on the secondary side of the switch power supplies, by a similar effect, it becomes easy to prevent noise of a specific frequency component from being markedly enhanced and to perform noise removal by means of power source filters on the secondary side (107a, 107b and 107c in FIG. 2). There generally are two kinds of noise as that of a switching power supply, which are respectively referred to as normal mode noise and common mode noise, and the both kinds of noise can be dealt with in the present example embodiment.

Further, a CPU is used for control of the switching power supplies in the present example embodiment. A control program for the switching power supplies is added to a program to operate the CPU. Accordingly, by thus making the CPU generate switching signals, instead of providing a switching controller, size and cost reduction of the whole circuit becomes possible.

Further, the AD converter 103 is provided in the present example embodiment. It has become general in recent products that an AD converter is provided for the purpose of voltage monitoring, and output of such an AD converter may be used. Accordingly, there is no need of adding a new component.

Further, for the switching power supplies 101a, 101b and 101c, not only a switching power supply of a PWM method but also that of a frequency control method, and the like, may be used.

### Third Example Embodiment

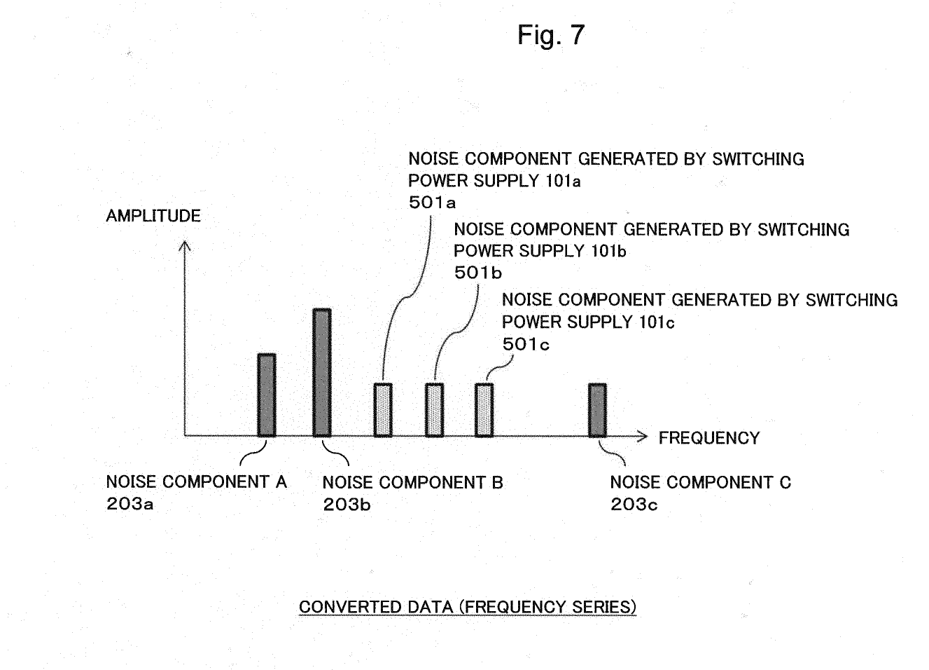

It is assumed in the second example embodiment that switching frequencies of respective ones of a plurality of switching power supplies are the same. However, switching frequencies of the plurality of switching power supplies 101a, 101b and 101c may be set to be different from each other. In that case, as shown in FIG. 7, frequencies of noise components 501a, 501b and 501c generated by the respective switching power supplies 101a, 101b and 101c become different from each other. Accordingly, further noise level reduction becomes possible.

### Fourth Example Embodiment

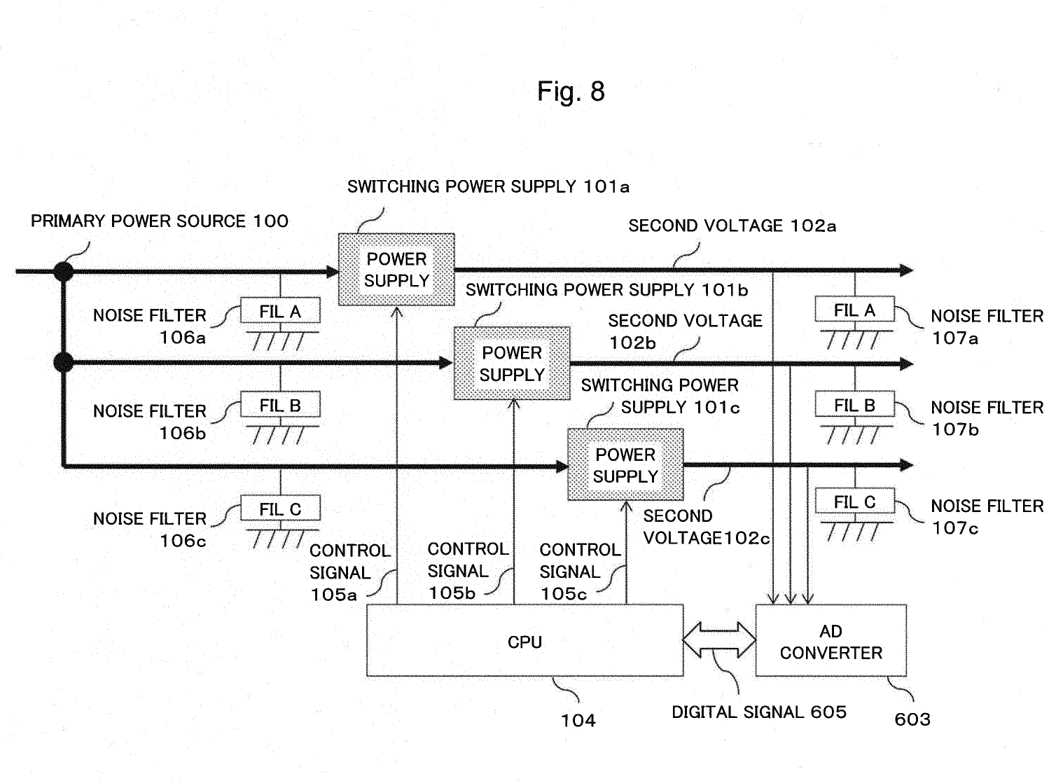

In the first to third example embodiments, frequencies of noise components are detected from the primary power source side. However, the detection may be performed from the secondary side, as shown in FIG. 8. An AD converter 603 measures the secondary voltages 102a, 102b and 102c corresponding to secondary power sources and outputs a digital signal 605 obtained by AD conversion of the measured values, to the CPU 104. Subsequent operation is similar to that in the first to third example embodiments. Because a user knows switching frequencies of switching power supplies, such as DC-DC converters, managed by the user, the user can identify any other frequency than the switching frequencies as that of noise.

### Fifth Example Embodiment

In the first to fourth example embodiments, a frequency used as a switching frequency is that which overlaps with none of frequencies of a plurality of noise components present in the primary power source or the secondary power source. However, when some of the plurality of noise components has a very small amplitude, a total of the amplitude of the small amplitude noise and that of noise generated by the switching power supplies may be within a range where noise removal by noise filters is possible. In that case, a switching frequency is allowed to overlap with a frequency of such a noise component having a small amplitude.

Specifically, setting a voltage amplitude able to be removed by noise filters as a threshold value, a switching frequency may be determined by a criterion that the switching frequency is allowed to overlap with noise if the noise is at a lower level than the threshold value. According to the present example embodiment, flexibility in determining a switching frequency is increased.

### Sixth Example Embodiment

In the first to fifth example embodiments, a frequency of a small amount of noise component is identified before starting operation of the switching power supplies. However, there is no restriction to that, but the identification may be performed during operation of the switching power supplies. It is effective when there is a possibility of temporal variation of noise components. Further, the identification may be performed both before starting and during the operation.

Here, the noise frequency analysis device of the present invention may be implemented either by a dedicated device or by a CPU (computer) as described in the second example embodiment. The computer reads a software program stored in a memory (not illustrated), executes the read software program in the CPU, and thereby outputs control signals corresponding to the execution result to the switching power supplies. In the case of each of the above-described example embodiments, it is only necessary for the software program to be provided with descriptions enabling to realize the above-described functions of the CPU and the switching power supplies. Further, also a computer-readable recording medium storing the software program may be regarded as constituting the present invention.

As above, the present invention has been described with reference to the example embodiments. However, the technical scope of the present invention is not limited to the range described in the above-described example embodiments and their modified examples. It is obvious to those skilled in the art that various modifications and improvements may be made to the example embodiments. In such a case, any additional example embodiment achieved by making such a modification or an improvement may be embraced within the technical scope of the present invention.

This application is based upon and claims the benefit of priority from Japanese Patent Application No. 2015-181327, filed on Sep. 15, 2015, the disclosure which is incorporated herein in its entirety by reference.

### REFERENCE SIGNS LIST

100 primary power source
101 switching power supply
102, 102a, 102b, 102c second voltage
103 AD converter
104 CPU
304 noise frequency analysis device
105, 105a, 105b, 105c control signal
106a, 106b, 106c, 107a, 107b, 107c noise filter
108, 605 digital signal
201 original data
202 converted data
203a, 203b, 203c noise component
501a, 501b, 501c noise component
603 AD converter

What is claimed is:

1. A switching power supply apparatus comprising:
a switching power supply configured to perform switching of input from a primary power source and thereby output a secondary power source; and
a noise frequency analysis device configured to analyze frequency components of noise included in output of the primary power source or of the secondary power source, and accordingly cause the switching power supply to perform switching at a different frequency from a frequency of a maximum noise amplitude among the frequency components.

2. The switching power supply apparatus according to claim 1,
wherein a plurality of switching power supplies according to claim 1 are provided between the primary power source and the secondary power source, the switching power supplies being coupled in parallel with each other, and
wherein the noise frequency analysis device causes each of the switching power supplies to perform switching at a different frequency from a frequency of a maximum noise amplitude among the analyzed noise frequency components.

3. The switching power supply apparatus according to claim 1,
wherein, when there are a plurality of frequency components of noise included in output of the primary power source or of the secondary power source, the noise frequency analysis device causes each of the switching power supplies to perform switching at a different frequency from any of the plurality of frequency components of noise.

4. The switching power supply apparatus according to claim 1,
wherein FFT (Fast Fourier Transform) is used for the analysis of noise frequencies on the primary power source or on the secondary power source.

5. The switching power supply apparatus according to claim 1, further comprising an AD converter configured to convert variation of output voltage of the primary power source or of the secondary power source into digital data and output the digital data to the noise frequency analysis device.

6. The switching power supply apparatus according to claim 1, further comprising noise filters between the primary power source and the switching power supplies and also between the secondary power source and the switching power supplies.

7. The switching power supply apparatus according to claim 1,
wherein the analysis of frequency components of noise is performed before starting operation of the switching power supplies.

8. The switching power supply apparatus according to claim 1,
wherein the switching power supplies are each a DC-DC converter.

9. A driving method for a switching power supply configured to perform switching of input from a primary power source and thereby output a secondary power source, the driving method comprising:
analyzing frequency components included in output of the primary power source or of the secondary power source; and
causing the switching power supply to perform switching at a different frequency from a frequency of a maximum noise amplitude among the frequency components.

10. A non-transitory computer-readable recording medium that records a program performing a driving for a switching power supply configured to perform switching of input from a primary power source and thereby output a secondary power source, the driving program causing a computer to execute:
a process of analyzing frequency components included in output of the primary power source or of the secondary power source; and
a process of causing the switching power supply to perform switching at a different frequency from a frequency of a maximum noise amplitude among the frequency components.
